(19) United States
(12) Patent Application Publication
(10) Pub. No.: US 2026/0173763 A1
(43) Pub. Date: Jun. 18, 2026

(54) VIBRATOR ELEMENT AND VIBRATOR DEVICE

(71) Applicant: SEIKO EPSON CORPORATION, Tokyo (JP)

(72) Inventor: Osamu Kawauchi, Shiojiri-shi (JP)

(21) Appl. No.: 19/416,613

(22) Filed: Dec. 11, 2025

(30) Foreign Application Priority Data
Dec. 13, 2024 (JP) 2024-218502

(51) Int. Cl. H10N 30/87; H10N 30/20; H10N 30/88

(52) U.S. Cl. CPC H10N 30/872; H10N 30/20; H10N 30/88

(57) ABSTRACT

A vibrator element includes: a piezoelectric substrate; an electrode provided on the piezoelectric substrate; and a bump provided on a surface of the electrode, a cross-sectional shape of the bump taken along a thickness direction of the piezoelectric substrate includes a first portion and a second portion protruding from the first portion, the first portion has a first side and a second side extending from the surface of the electrode, the second portion has a third side intersecting the first side and a fourth side intersecting the second side, and a width of the second portion in a direction orthogonal to the thickness direction is larger than a width of the first portion in the direction orthogonal to the thickness direction.

The present application is based on, and claims priority from JP Application Serial Number 2024-218502, filed Dec. 13, 2024, the disclosure of which is hereby incorporated by reference herein in its entirety.

### BACKGROUND

### 1. Technical Field

The present disclosure relates to a vibrator element and a vibrator device.

### 2. Related Art

A vibrator device in which a vibrator element is housed in a package is applied to, for example, a mobile communication device such as a mobile phone.

For example, JP-A-2014-82538 discloses a piezoelectric vibrator including a housing having a base and a cover, a piezoelectric vibrator element having a joining member formed on its surface, and a bump for joining the piezoelectric vibrator element to the base via the joining member.

In the piezoelectric vibrator as described above, a space is required between the piezoelectric vibrator element and the base so that the vibration of the piezoelectric vibrator element is not inhibited by the base. In JP-A-2014-82538, since the bump is deformed when the piezoelectric vibrator element is joined to the base, the space is ensured by the joining member. However, in JP-A-2014-82538, the process of forming the joining member is necessary, and thus the production efficiency decreases.

### SUMMARY

An aspect of a vibrator element according to the present disclosure includes: a piezoelectric substrate; an electrode provided on the piezoelectric substrate; and a bump provided on a surface of the electrode, a cross-sectional shape of the bump taken along a thickness direction of the piezoelectric substrate includes a first portion and a second portion protruding from the first portion, the first portion has a first side and a second side extending from the surface of the electrode, the second portion has a third side intersecting the first side and a fourth side intersecting the second side, and a width of the second portion in a direction orthogonal to the thickness direction is larger than a width of the first portion in the direction orthogonal to the thickness direction.

An aspect of a vibrator device according to the present disclosure includes: the vibrator element mentioned above; and a case including a coupling terminal and housing the vibrator element, and the second portion of the bump is coupled to the coupling terminal.

An aspect of a vibrator device according to the present disclosure includes: the vibrator element mentioned above; a case including a coupling terminal and housing the vibrator element; and a joining member fixing the bump to the coupling terminal, and the joining member reaches to an inner corner portion where the first side and the third side of the bump intersect each other and an inner corner portion where the second side and the fourth side of the bump intersect each other.

### BRIEF DESCRIPTION OF THE DRAWINGS

FIG. 1 is a cross-sectional view schematically illustrating a vibrator device according to a first embodiment.

FIG. 2 is a plan view schematically illustrating a vibrator element of the vibrator device according to the first embodiment.

FIG. 3 is a cross-sectional view schematically illustrating the vibrator element of the vibrator device according to the first embodiment.

FIG. 4 is a cross-sectional view schematically illustrating the vibrator element of the vibrator device according to the first embodiment.

FIG. 5 is a cross-sectional view schematically illustrating the vibrator element of the vibrator device according to the first embodiment.

FIG. 6 is a cross-sectional view schematically illustrating a manufacturing process of the vibrator element of the vibrator device according to the first embodiment.

FIG. 7 is a cross-sectional view schematically illustrating a manufacturing process of the vibrator element of the vibrator device according to the first embodiment.

FIG. 8 is a cross-sectional view schematically illustrating a manufacturing process of the vibrator element of the vibrator device according to the first embodiment.

FIG. 9 is a cross-sectional view schematically illustrating a manufacturing process of the vibrator element of the vibrator device according to the first embodiment.

FIG. 10 is a cross-sectional view schematically illustrating a manufacturing process of the vibrator element of the vibrator device according to the first embodiment.

FIG. 11 is a cross-sectional view schematically illustrating a manufacturing process of the vibrator element of the vibrator device according to the first embodiment.

FIG. 12 is a cross-sectional view schematically illustrating a manufacturing process of the vibrator element of the vibrator device according to the first embodiment.

FIG. 13 is a cross-sectional view schematically illustrating a manufacturing process of the vibrator element of the vibrator device according to the first embodiment.

FIG. 14 is a cross-sectional view schematically illustrating a manufacturing process of the vibrator element of the vibrator device according to the first embodiment.

FIG. 15 is a plan view schematically illustrating a vibrator element of a vibrator device according to a modification of the first embodiment.

FIG. 16 is a cross-sectional view schematically illustrating a vibrator device according to a second embodiment.

FIG. 17 is a cross-sectional view schematically illustrating a vibrator device according to a first modification of the second embodiment.

FIG. 18 is a cross-sectional view schematically illustrating a first bump of a vibrator device according to a second modification of the second embodiment.

FIG. 19 is a cross-sectional view schematically illustrating a first bump of a vibrator device according to the second modification of the second embodiment.

FIG. 20 is a cross-sectional view schematically illustrating a first bump of a vibrator device according to the second modification of the second embodiment.

### DESCRIPTION OF EMBODIMENTS

Hereinafter, preferred embodiments of the present disclosure will be described in detail with reference to the drawings. The embodiments to be described below do not unduly limit the content of the present disclosure described in the claims. In addition, all of the configurations described below are not necessarily essential components of the present disclosure.

### 1. First Embodiment

### 1.1. Vibrator Device

### 1.1.1 Overall Configuration

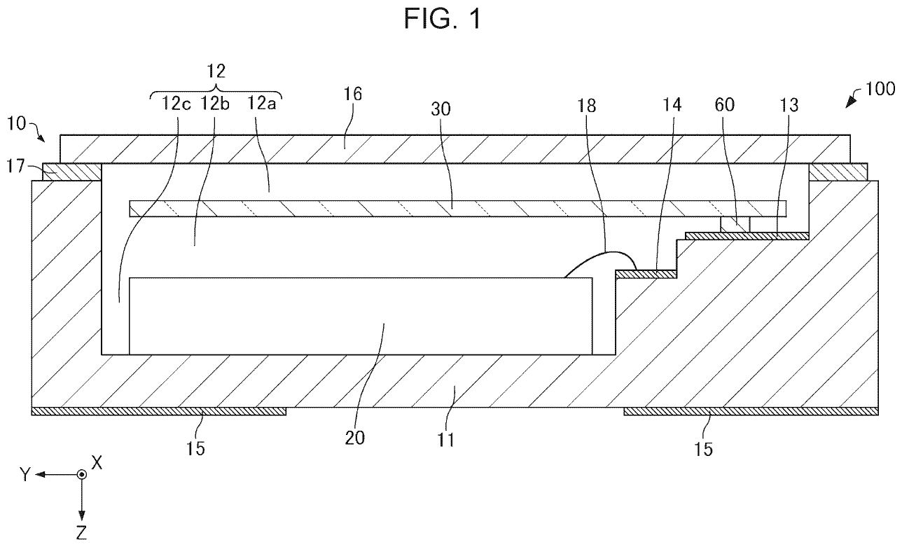

First, a vibrator device according to a first embodiment will be described with reference to the drawings. FIG. 1 is a cross-sectional view schematically illustrating the vibrator device 100 according to the first embodiment. In FIG. 1, an X-axis, a Y-axis, and a Z-axis are shown as three axes orthogonal to each other.

As illustrated in FIG. 1, the vibrator device 100 includes a case 10, a circuit element 20, and a vibrator element 30. The vibrator device 100 is, for example, an oscillator. For convenience, the vibrator element 30 is illustrated in a simplified manner in FIG. 1.

The case 10 houses the circuit element 20 and the vibrator element 30. The case 10 is a package. The case 10 includes, for example, a base 11, coupling terminals 13 and 14, external terminals 15, and a lid 16.

The material of the base 11 is, for example, a ceramic such as alumina. A recessed portion 12 open to the upper surface is formed in the base 11. The circuit element 20 and the vibrator element 30 are housed in a space formed by the recessed portion 12. The space of the recessed portion 12 is airtight and in a reduced pressure state, preferably in a state close to vacuum. Thereby, the viscous resistance is reduced, and the vibration characteristics of the vibrator element 30 are improved. The space of the recessed portion 12 may be a sealed atmosphere of an inert gas such as nitrogen or argon.

The recessed portion 12 formed in the base 11 includes, for example, a first recessed portion 12a open to the upper face of the base 11, a second recessed portion 12b formed on the bottom side of the first recessed portion 12a, and a third recessed portion 12c formed on the bottom side of the second recessed portion 12b. The opening width of the second recessed portion 12b is smaller than the opening width of the first recessed portion 12a. The opening width of the third recessed portion 12c is smaller than the opening width of the second recessed portion 12b.

The coupling terminal 13 is provided on the bottom surface of the first recessed portion 12a. The coupling terminal 14 is provided on the bottom surface of the second recessed portion 12b. The coupling terminals 13 and 14 are electrically coupled to each other via wiring (not illustrated). The external terminals 15 are provided on the outer bottom surface of the base 11. The external terminals 15 are electrically coupled to the coupling terminals 13 and 14 via wiring (not illustrated). The external terminals 15 are configured to be coupled to, for example, an external member (not illustrated). The coupling terminals 13 and 14 and the external terminals 15 are, for example, multilayer members formed by stacking a nickel (Ni) layer and a gold (Au) layer in this order on the base 11.

The lid 16 is joined to the base 11. The lid 16 and the base 11 are joined together by, for example, providing a seal ring 17 on the base 11, mounting the lid 16 on the seal ring 17, and welding the seal ring 17 to the base 11 using a resistance welding machine. The joining between the base 11 and the lid 16 is not particularly limited, and may be performed by using an adhesive or by seam welding.

The material of the lid 16 is, for example, a metal such as Kovar or a glass having optical transparency. The lid 16 seals the opening of the recessed portion 12. The lid 16 has, for example, a plate shape.

The circuit element 20 is joined to the bottom surface of the third recessed portion 12c. The circuit element 20 includes, for example, an interface section that communicates with an external host device, and an oscillation circuit that oscillates the vibrator element 30. The circuit element 20 is electrically coupled to the coupling terminal 14 via a wire bonding portion 18.

The vibrator element 30 is joined to the coupling terminal 13. The vibrator element 30 is electrically coupled to the circuit element 20 via the coupling terminals 13 and 14 and the wire bonding portion 18. When a drive signal is applied from the circuit element 20 to the vibrator element 30, the vibrator element 30 oscillates at a predetermined frequency.

In the present embodiment, the circuit element 20 is provided in the third recessed portion 12c of the base 11. However, it is also possible to use a semiconductor substrate in which an integrated-circuit unit including an oscillation circuit is formed on a flat silicon substrate (not illustrated). By disposing the vibrator element 30 on the semiconductor substrate and sealing the vibrator element 30 with a lid having a recessed portion, the circuit element and the recessed portion of the base become unnecessary, and thus it is possible to downsize the vibrator device.

The vibrator device 100 may alternatively be a resonator having only a vibrator element mounted on a base. In the resonator (not illustrated), the vibrator element is coupled to an oscillation circuit disposed in an external member via a coupling terminal of the base and an external terminal.

Further, the disclosure may be used as a device other than an oscillator or a resonator, for example, as various sensors such as an acceleration sensor and an angular velocity sensor. The vibrator device 100 may be included in a computer, a printer, a smartphone, a tablet terminal, a watch, a television, a head-mounted display, a video camera, a digital still camera, a car navigation device, an electronic game device, various medical devices, various measurement devices, various vehicles, and the like.

### 1.1.2. Vibrator Element

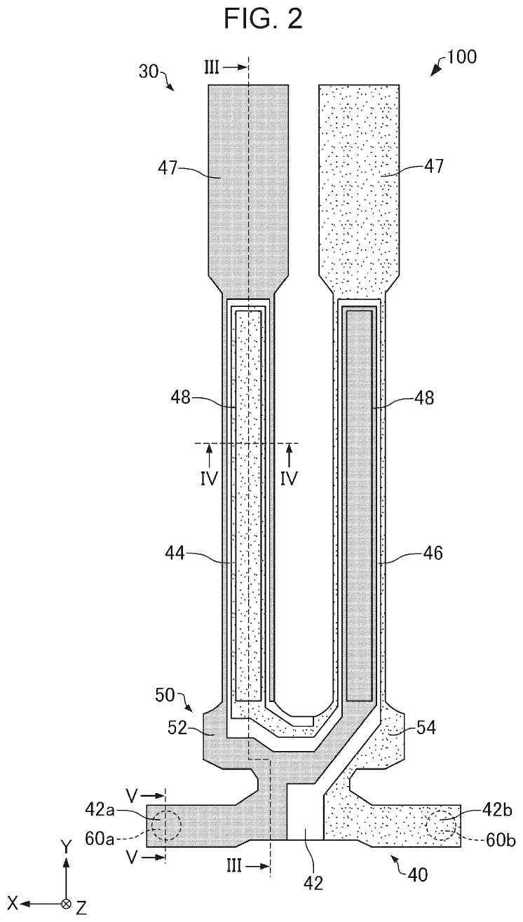

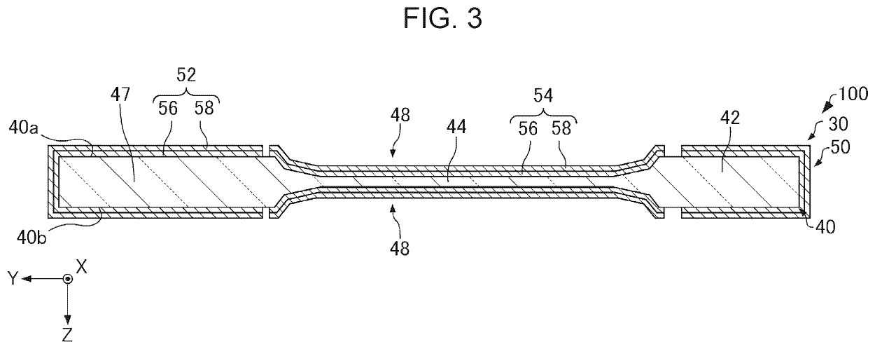

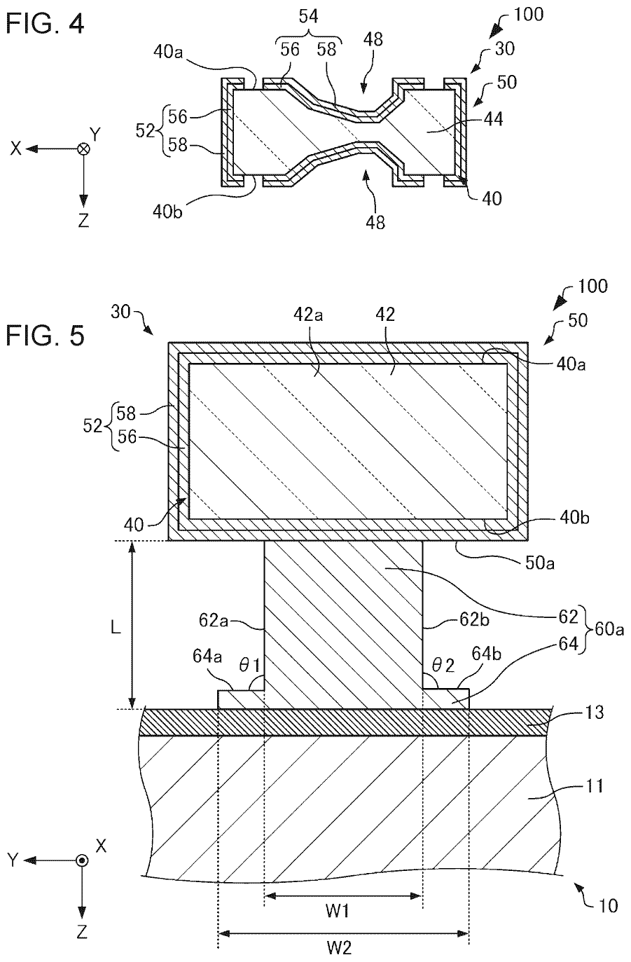

FIG. 2 is a plan view schematically illustrating the vibrator element 30. FIG. 3 is a cross-sectional view schematically illustrating the vibrator element 30 taken along line III-III in FIG. 2. FIG. 4 is a cross-sectional view schematically illustrating the vibrator element 30 taken along line IV-IV in FIG. 2. FIG. 5 is a cross-sectional view schematically illustrating the vibrator element 30 taken along line V-V in FIG. 2.

As illustrated in FIGS. 2 to 5, the vibrator element 30 includes, for example, a piezoelectric substrate 40, electrodes 50, a first bump 60a, and a second bump 60b.

The piezoelectric substrate 40 is, for example, a Z-cut quartz crystal plate. The vibrator element 30 is, for example, a quartz crystal vibrator element of a tuning fork type. In the illustrated example, the piezoelectric substrate 40 has a flat plate shape that extends in the XY plane defined by the X-axis and the Y-axis and has the thickness in the Z-axis direction. The X-axis, the Y-axis, and the Z-axis respectively correspond to an electric axis, a mechanical axis, and an optical axis, which are crystal axes of a quartz crystal. The constituent material of the piezoelectric substrate 40 is not particularly limited, and various piezoelectric materials such as lead zirconate titanate may be used.

As illustrated in FIG. 2, the piezoelectric substrate 40 includes, for example, a base portion 42, a first vibration arm 44, and a second vibration arm 46.

The base portion 42 supports the first vibration arm 44 and the second vibration arm 46. The base portion 42 has a first fixed portion 42a overlapping the first bump 60a and a second fixed portion 42b overlapping the second bump 60b in a plan view. In the illustrated example, the fixed portions 42a and 42b have shapes extending in the X-axis direction. The first fixed portion 42a is located in the +X-axis direction relative to the first vibration arm 44. The second fixed portion 42b is located in the −X-axis direction relative to the second vibration arm 46.

The first vibration arm 44 and the second vibration arm 46 extend from the base portion 42 in the +Y-axis direction. In the illustrated example, the first vibration arm 44 is located in the +X-axis direction relative to the second vibration arm 46. The vibration arms 44 and 46 have, for example, wide portions 47 having a large width in the X-axis direction at the tip ends opposite to the base portion 42. The masses of the vibration arms 44 and 46 can be increased by forming the wide portions 47, and the size of the vibrator element 30 can be reduced.

Grooves 48 are formed in the first vibration arm 44 and the second vibration arm 46. As illustrated in FIG. 4, the grooves 48 are formed on a first main surface 40a and a second main surface 40b of the piezoelectric substrate 40, which face in the opposite directions. Each of the vibration arms 44 and 46 has a substantially H-shaped cross-sectional shape due to the presence of the grooves 48. The crystal impedance (CI) value of the vibrator element 30 can be reduced by forming the grooves 48. In the illustrated example, the first main surface 40a faces the −Z-axis direction. The second main surface 40b faces the +Z-axis direction.

The electrodes 50 are provided on the piezoelectric substrate 40. The electrodes 50 include a first electrode layer 52 and a second electrode layer 54. The first electrode layer 52 and the second electrode layer 54 are separated from each other. The electrode layers 52 and 54 are provided on the main surfaces 40a and 40b and the side surfaces of the base portion 42. To be specific, the first electrode layer 52 is provided on the main surfaces 40a and 40b and the side surfaces of the first fixed portion 42a. The second electrode layer 54 is provided on the main surfaces 40a and 40b and the side surfaces of the second fixed portion 42b. The side surfaces connect the main surfaces 40a and 40b.

The first electrode layer 52 is further provided on the side surfaces of the first vibration arm 44 and the inner surfaces of the grooves 48 formed in the second vibration arm 46. The second electrode layer 54 is provided on the inner surfaces of the grooves 48 formed in the first vibration arm 44 and the side surfaces of the second vibration arm 46.

Each of the first electrode layer 52 and the second electrode layer 54 includes a first metal layer 56 and a second metal layer 58. The first metal layer 56 is provided on the piezoelectric substrate 40. The first metal layer 56 is provided between the piezoelectric substrate 40 and the second metal layer 58. The first metal layer 56 is, for example, a chromium (Cr) layer. The second metal layer 58 is provided on the first metal layer 56. The second metal layer 58 is, for example, a gold layer.

The first electrode layer 52 is coupled to the first bump 60a. The first electrode layer 52 is electrically coupled to the circuit element 20 via the first bump 60a. The second electrode layer 54 is coupled to the second bump 60b. The second electrode layer 54 is electrically coupled to the circuit element 20 via the second bump 60b. When a drive signal is applied from the circuit element 20 to the electrode layers 52 and 54, the first vibration arm 44 and the second vibration arm 46 vibrate at a predetermined frequency.

As illustrated in FIG. 5, the first bump 60a is provided between the base 11 and the piezoelectric substrate 40. The first bump 60a is provided on a surface 50a of an electrode 50. The first bump 60a is joined to the coupling terminal 13. The first bump 60a is metal-bonded to the coupling terminal 13. The material of the first bump 60a is, for example, a metal such as gold.

The length L of the first bump 60a in the Z-axis direction is, for example, not less than 10 μm and not more than 100 μm. The length L corresponds to the thickness of the first bump 60a. The length L, the width described later, and the like of the first bump 60a are measured with, for example, a scanning electron microscope (SEM). As illustrated in FIG. 5, the first bump 60a has a first portion 62 and a second portion 64 in a cross-sectional shape taken along the Z-axis direction, which is the thickness direction of the piezoelectric substrate 40.

The first portion 62 of the first bump 60a is provided between the second portion 64 and the piezoelectric substrate 40. The first portion 62 is in contact with the first electrode layer 52 of the electrode 50. The first portion 62 has a first side 62a and a second side 62b extending from the surface 50a of the electrode 50. In the illustrated example, the first side 62a and the second side 62b extend in the +Z-axis direction from the surface 50a of the electrode 50. The first side 62a and the second side 62b are orthogonal to the surface 50a. The first side 62a and the second side 62b are parallel to each other, for example. In the illustrated example, the shape of the first portion 62 is rectangular.

The second portion 64 of the first bump 60a is provided between the coupling terminal 13 and the first portion 62. The second portion 64 protrudes from the first portion 62 to the side opposite to the first electrode layer 52. In the illustrated example, the second portion 64 protrudes from the first portion 62 in the +Z-axis direction. The second portion 64 is connected to the coupling terminal 13. The width W2 of the second portion 64 is larger than the width W1 of the first portion 62. The widths W1 and W2 are widths in a direction orthogonal to the thickness direction of the piezoelectric substrate 40. The width W1 is the maximum width of the first portion 62. The width W2 is the maximum width of the second portion 64. The width W2 of the second portion 64 is larger than the length of the second portion 64 in the Z-axis direction. The length of the second portion 64 in the Z-axis direction is shorter than the length of the first portion 62 in the Z-axis direction.

The second portion 64 of the first bump 60a has a third side 64a intersecting the first side 62a and a fourth side 64b intersecting the second side 62b. In the illustrated example, the angle θ1 at which the first side 62 a and the third side 64 a intersect each other is 90°. The angle θ2 at which the second side 62b and the fourth side 64b intersect each other is 90°. Note that the angles θ1 and θ2 are angles at which the surfaces of the first portion 62 and the surfaces of the second portion 64 intersect. For example, the third side 64a and the fourth side 64b are parallel to the surface 50a of the electrode 50. In the illustrated example, the shape of the second portion 64 is rectangular.

The second bump 60b is coupled to the second electrode layer 54. The shape and material of the second bump 60b are basically the same as the shape and material of the first bump 60a. Therefore, description thereof is omitted.

The vibrator element 30 is not limited to a vibrator element of a tuning fork type and may be, for example, an AT vibrator element.

### 1.1.3. Method of Manufacturing Vibrator Element

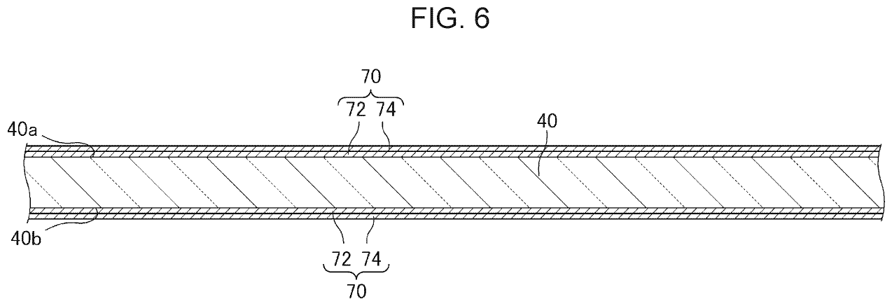

Next, a method of manufacturing the vibrator element 30 will be described with reference to the drawings. FIGS. 6 to 14 are cross-sectional views schematically illustrating manufacturing processes for the vibrator element 30. FIGS. 6 to 11 correspond to the cross-sectional view taken along line III-III illustrated in FIG. 2. FIGS. 12 to 14 correspond to the cross-sectional view taken along line V-V illustrated in FIG. 2.

As illustrated in FIG. 6, mask layers 70 are formed on the first main surface 40a and the second main surface 40b of the piezoelectric substrate 40. Specifically, chromium layers 72 are formed on the piezoelectric substrate 40, gold layers 74 are formed on the chromium layers 72, so that the mask layers 70 each including a chromium layer 72 and a gold layer 74 are formed. The chromium layers 72 and the gold layers 74 are formed by, for example, sputtering.

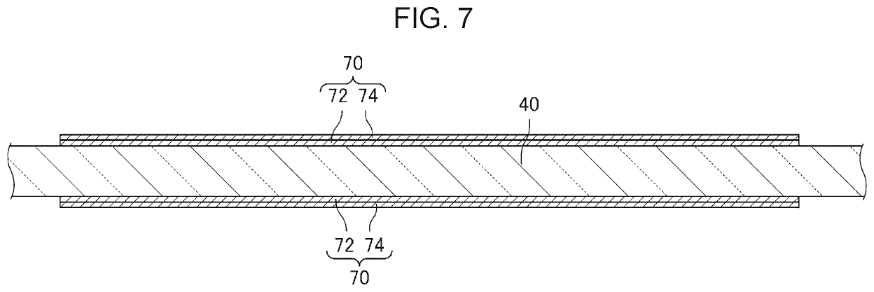

As illustrated in FIG. 7, the mask layers 70 are patterned. The patterning is performed by, for example, photolithography and etching.

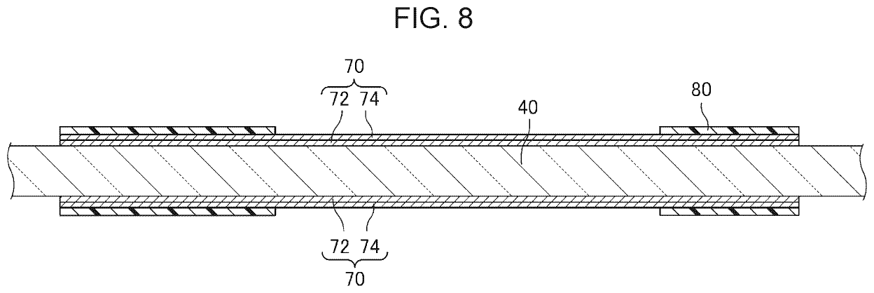

As illustrated in FIG. 8, first resist layers 80 are formed on the mask layers 70. The first resist layers 80 are formed into predetermined shapes by, for example, photolithography.

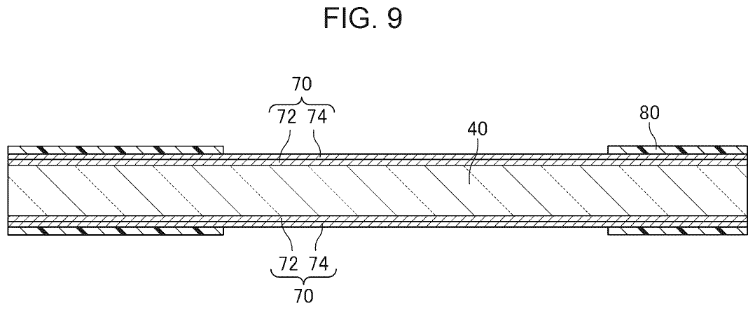

As illustrated in FIG. 9, the piezoelectric substrate 40 is etched by using the mask layers 70 as masks. The outer shape of the piezoelectric substrate 40 is formed by the etching.

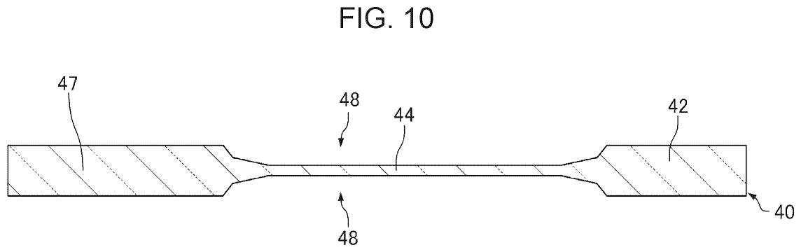

As illustrated in FIG. 10, the mask layers 70 are etched by using the first resist layers 80 as masks, and the piezoelectric substrate 40 is etched to form the grooves 48. Next, the first resist layers 80 are stripped, and the mask layers 70 are removed by etching.

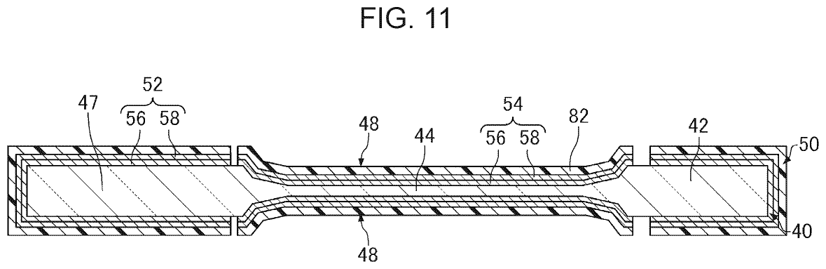

As illustrated in FIG. 11, the electrodes 50 are formed on the piezoelectric substrate 40. The electrodes 50 are formed by, for example, sputtering. Next, second resist layers 82 are formed on the electrodes 50. The second resist layers 82 are formed into predetermined shapes by, for example, photolithography. Next, the electrodes 50 are etched by using the second resist layers 82 as masks to form the first electrode layer 52 and the second electrode layer 54.

As illustrated in FIG. 3, the second resist layers 82 are stripped.

As illustrated in FIG. 12, a third resist layer 84 is formed on the electrodes 50. The third resist layer 84 is formed into a predetermined shape by, for example, photolithography.

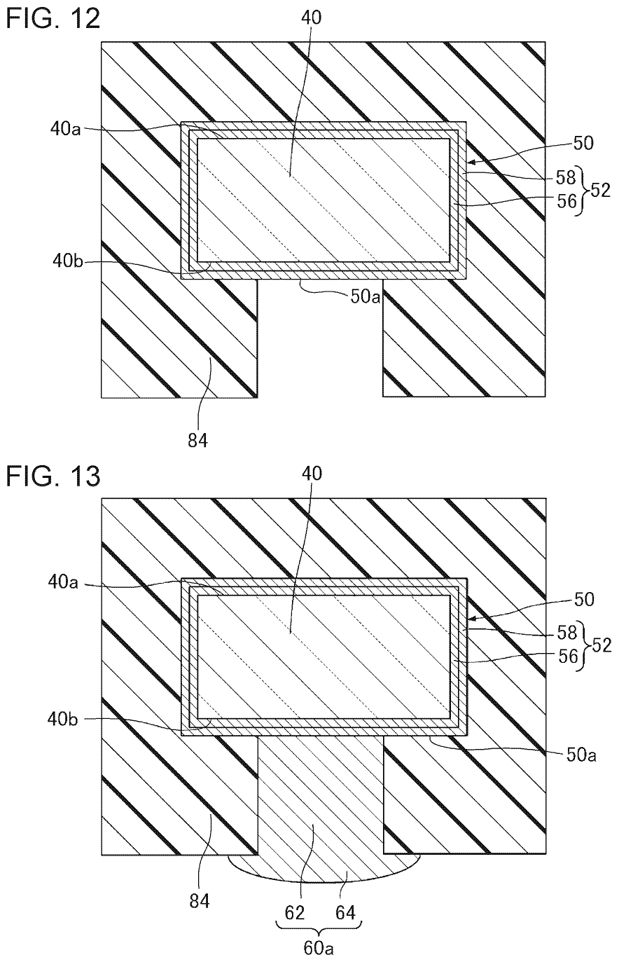

As illustrated in FIG. 13, the first bump 60a is formed on the first electrode layer 52. The first bump 60a is formed by, for example, an electroless plating method. In the illustrated example, the first portion 62 of the first bump 60a is surrounded by the third resist layer 84. The second portion 64 of the first bump 60a protrudes from the third resist layer 84. The first bump 60a is longer in the Z-axis direction than the third resist layer 84. In the illustrated example, the second portion 64 has an arcuate shape in the vicinity of the distal end.

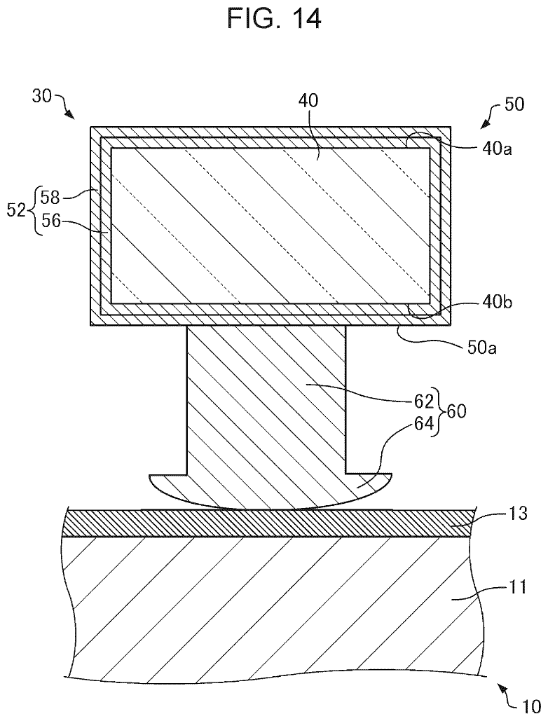

As illustrated in FIG. 14, the third resist layer 84 is stripped. Then, the first bump 60a is mounted on the coupling terminal 13.

As illustrated in FIG. 5, the first bump 60a is metal-bonded to the coupling terminal 13 of the case 10. This bonding is carried out by pressing the first bump 60a against the coupling terminal 13 while heating it, for example, in a state in which the coupling terminal 13 has a higher temperature than the first bump 60a. Since the second portion 64 is wider than the first portion 62, heat is easily transferred from the coupling terminal 13 to the second portion 64. Thus, as illustrated in FIG. 5, the second portion 64 can be selectively deformed while the first portion 62 is not deformed.

The second bump 60b is formed on the second electrode layer 54 in the same process as the first bump 60a by the same method as the first bump 60a. The second bump 60b is joined to the case 10 in the same manner as the first bump 60a.

As described above, the vibrator element 30 joined to the case 10 can be manufactured.

### 1.1.4. Operational Advantage

The vibrator element 30 includes the piezoelectric substrate 40, the electrodes 50 provided on the piezoelectric substrate 40, and the first bump 60a provided on the surface 50a of an electrode 50. The first bump 60a includes the first portion 62 and the second portion 64 protruding from the first portion 62 in a cross-sectional shape taken along the thickness direction of the piezoelectric substrate 40. The first portion 62 has the first side 62a and the second side 62b extending from the surface 50a of the electrode 50. The second portion 64 has the third side 64a intersecting the first side 62a and the fourth side 64b intersecting the second side 62b. The width W2 of the second portion 64 is larger than the width W1 of the first portion 62.

Therefore, in the vibrator element 30, a space between the piezoelectric substrate 40 and the coupling terminal 13 of the case 10 can be ensured by the first portion 62 of the first bump 60a. Therefore, it is not necessary to separately provide spacers between the bumps 60 and the electrodes 50. Therefore, as compared with the case where spacers are separately provided, the number of manufacturing steps can be reduced, and the production efficiency can be improved.

Further, in the vibrator element 30, as described above, the second portion 64 of the first bump 60a is selectively deformed at the time of joining to the coupling terminal 13, and thus it is possible to reduce the pressing distance of the first bump 60a at the time of joining. Therefore, it is possible to improve the joining strength while ensuring a space between the piezoelectric substrate 40 and the coupling terminal 13.

In the vibrator element 30, the third side 64a and the fourth side 64b are parallel to the surface 50a of the electrode 50. Therefore, in the first bump 60a of the vibrator element 30, the first portion 62 is formed to be as thick as the third resist layer 84, and in addition, the second portion 64 is provided. Thus, the first bump 60a can be formed to be thicker than the third resist layer 84 by the thickness of the second portion 64.

### 1.1.5. Modification of Vibrator Element

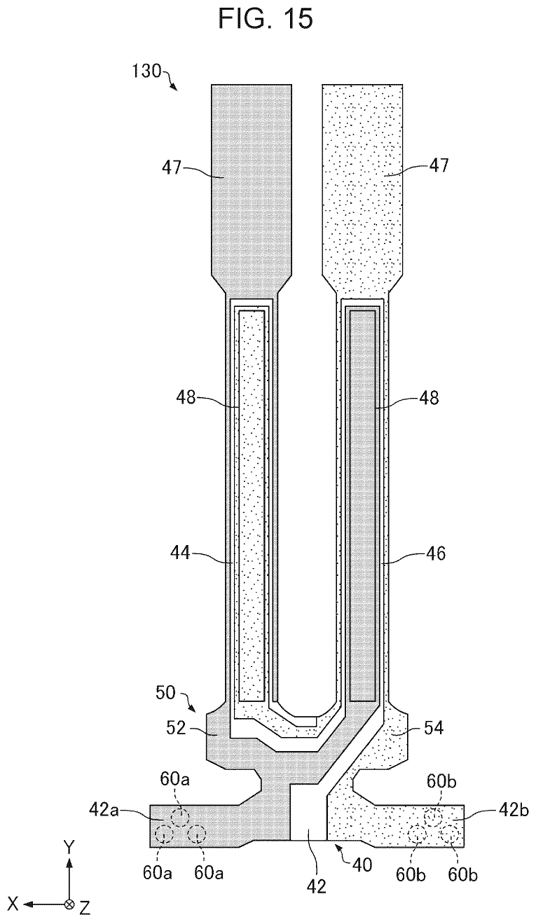

Next, a vibrator element according to a modification of the first embodiment will be described with reference to drawings. FIG. 15 is a plan view schematically illustrating a vibrator element 130 according to the modification of the first embodiment. Hereinafter, in the vibrator element 130 according to the modification of the first embodiment, the members having the same functions as the constituent members of the vibrator element 30 according to the first embodiment described above are denoted by the same reference numerals, and detailed description thereof will be omitted.

In the vibrator element 30 described above, as illustrated in FIG. 2, one first bump 60a is provided for the first fixed portion 42a. One second bump 60b is provided for the second fixed portion 42b.

In the vibrator element 130, as illustrated in FIG. 15, a plurality of first bumps 60a are provided for the first fixed portion 42a. A plurality of second bumps 60b are provided for the second fixed portion 42b. In the illustrated example, three first bump 60a are provided for the first fixed portion 42a. Three second bumps 60b are provided for the second fixed portion 42b.

The vibrator element 130 includes the plurality of first bumps 60a. Therefore, in the vibrator element 130, the contact area between the first bumps 60a and the first electrode layer 52 can be increased. Thus, the joining strength between the vibrator element 130 and the case 10 can be improved. Furthermore, the flatness of the piezoelectric substrate 40 can be improved.

### 2. Second Embodiment

### 2.1. Vibrator Device

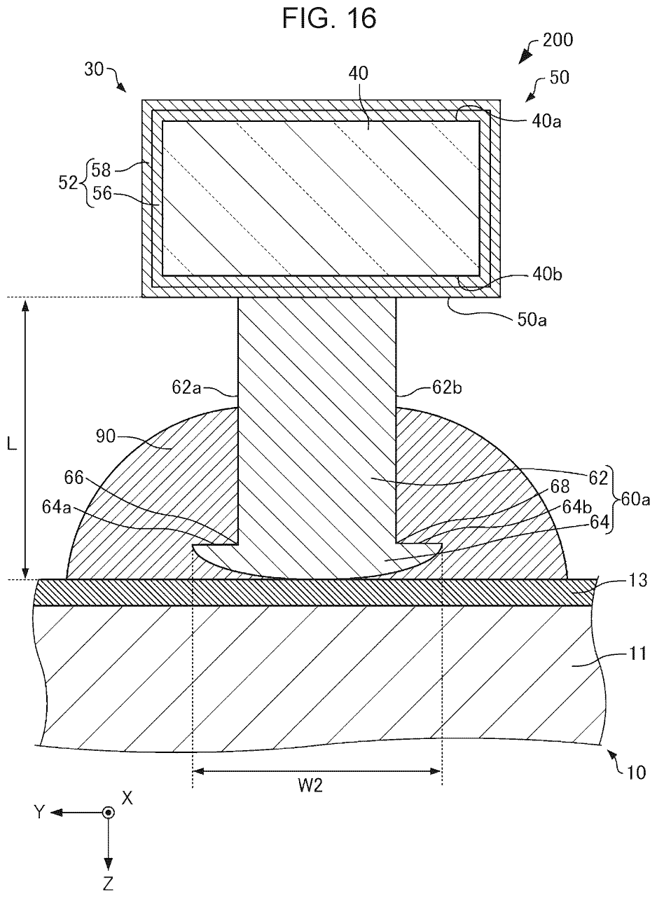

Next, a vibrator device according to a second embodiment will be described with reference to the drawings. FIG. 16 is a cross-sectional view schematically illustrating a vibrator device 200 according to the second embodiment. Hereinafter, in the vibrator device 200 according to the second embodiment, the members having the same functions as the constituent members of the vibrator device 100 according to the first embodiment described above are denoted by the same reference numerals, and detailed description thereof will be omitted.

As illustrated in FIG. 16, the vibrator device 200 is different from the above-described vibrator device 100 in that the vibrator device 200 includes a joining member 90.

As the joining member 90, for example, silver paste is used. The joining member 90 is softer than the first bump 60a. The Young modulus of the joining member 90 is, for example, lower than the Young modulus of the first bump 60a.

In the vibrator device 200, for example, the vibrator element 30 is mounted on the coupling terminal 13 in the state in which the second portion 64 of the first bump 60a is not deformed. The first bump 60a is not thermocompression-bonded to the coupling terminal 13. The first bump 60a is not metal-bonded to the coupling terminal 13. In the vibrator device 200, in a state where the first bump 60a is mounted on the coupling terminal 13, the joining member 90 in the form of paste is applied, and then the joining member 90 is cured by heating, so that the vibrator element 30 is fixed to the case 10.

The joining member 90 fixes the first bump 60a to the coupling terminal 13. As illustrated in FIG. 16, the joining member 90 reaches to a first inner corner portion 66 and a second inner corner portion 68 of the first bump 60a in the cross-sectional shape taken along the Z-axis direction. The joining member 90 covers the first inner corner portion 66 and the second inner corner portion 68. The first inner corner portion 66 is a portion where the first side 62a and the third side 64a of the first bump 60a intersect each other. The second inner corner portion 68 is a portion where the second side 62b and the fourth side 64b of the first bump 60a intersect each other.

The joining member 90 is separated from the first electrode layer 52. The length L of the first bump 60a in the Z-axis direction is, for example, 20 μm or more. The length L of the first bump 60a is, for example, larger than the width W2 of the second portion 64 of the first bump 60a.

In the vibrator device 200, for example, a second bump 60b is also fixed to the case 10 with a joining member 90 in the same manner as the first bump 60a.

In the vibrator device 200, the length L of the first bump 60 a is 20 μm or more. Therefore, when the vibrator element 30 is fixed to the case 10 in the vibrator device 200, it is possible to reduce the possibility that the joining member 90 is in contact with the electrode 50. Thus, the possibility that the joining member 90 is in contact with the piezoelectric substrate 40 can be reduced.

In the vibrator device 200, the joining member 90 reaches to the first inner corner portion 66 where the first side 62a and the third side 64a of the first bump 60a intersect each other and the second inner corner portion 68 where the second side 62b and the fourth side 64b of the first bump 60a intersect each other. Therefore, in the vibrator device 200, it is possible to improve the joining strength of the vibrator element 30 to the case 10 by the anchor effect due to the joining member 90 extending to the inner corner portions 66 and 68 of the first bump 60a. Therefore, since the joining strength is sufficiently large without increasing the size of the first bump 60a, downsizing can be achieved.

Further, since the joining member 90 is softer than the first bump 60a, it is possible to absorb the stress generated when the vibrator element 30 is joined to the case 10, compared to the case where the vibrator element 30 is joined to the case 10 by deforming the second portion 64 as in the vibrator device 100. Thus, vibration leakage of the piezoelectric substrate 40 can be reduced.

### 2.2. Modifications of Vibrator Device

### 2.2.1. First Modification

Next, a vibrator device according to a first modification of the second embodiment will be described with reference to the drawings. FIG. 17 is a cross-sectional view schematically illustrating a vibrator device 210 according to the first modification of the second embodiment.

Hereinafter, in the vibrator device 210 according to the first modification of the second embodiment, the members having the same functions as the constituent members of the vibrator device 200 according to the second embodiment described above are denoted by the same reference numerals, and detailed description thereof will be omitted. The same applies to a vibrator device according to a second modification of the second embodiment described later.

In the vibrator device 200 described above, as illustrated in FIG. 16, the joining member 90 is separated from the first electrode layer 52.

In contrast, in the vibrator device 210, as illustrated in FIG. 17, the joining member 90 is in contact with the first electrode layer 52. Therefore, in the vibrator device 210, it is possible to increase the contact area between the joining member 90 and the vibrator element 30. Thus, the joining strength between the vibrator element 30 and the case 10 can be improved.

### 2.2.2. Second Modification

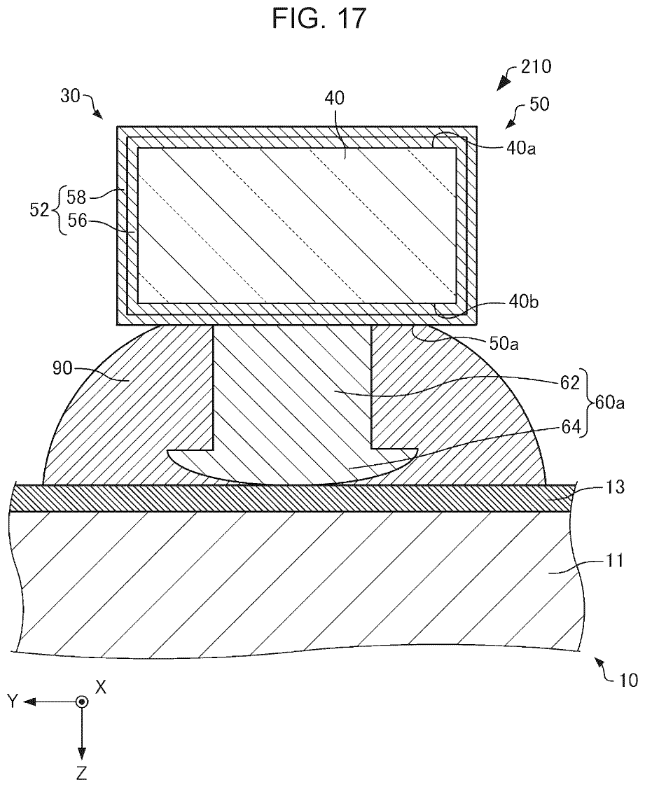

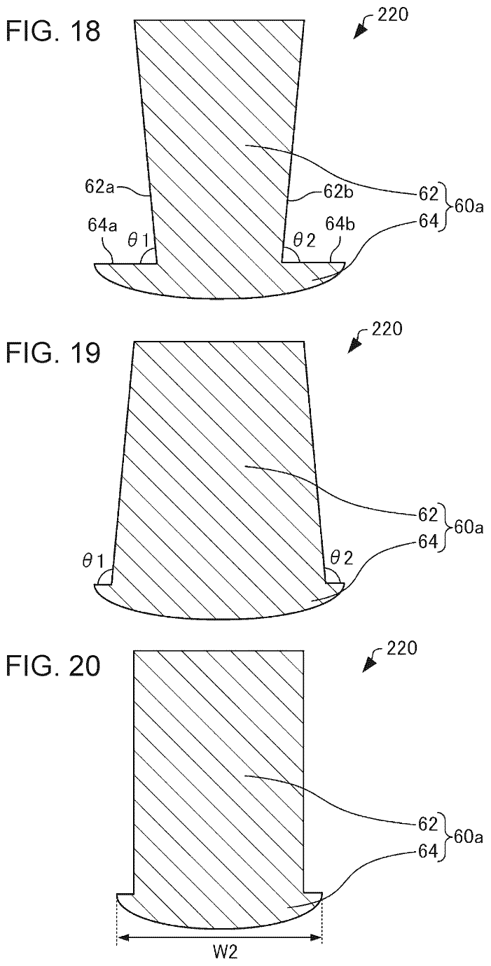

Next, a vibrator device according to the second modification of the second embodiment will be described with reference to the drawings. FIG. 18 is a cross-sectional view schematically illustrating a first bump 60a of a vibrator device 220 according to the second modification of the second embodiment.

In the vibrator device 220, the shape of the first bump 60a is different from the shape of the first bump 60a of the above-described vibrator device 200.

In the vibrator device 220, as illustrated in FIG. 18, in the first bump 60a, at least one of the angle θ1 at which a first side 62a and a third side 64a intersect each other and the angle θ2 at which a second side 62b and a fourth side 64 b intersect each other is less than 90°. In the illustrated example, both the angle θ1 and the angle θ2 are less than 90°. The angles θ1 and θ2 are, for example, 45° or more and less than 90°. In the case where at least one of the angle θ1 and the angle θ2 is less than 90°, when the vibrator element 30 is fixed to the case 10 with the joining member 90, the anchor effect increases, and the joining strength between the vibrator element 30 and the case 10 can be improved.

As illustrated in FIG. 19, at least one of the angle θ1 and the angle θ2 may be 90° or more. At least one of the angle θ1 and the angle θ2 may be more than 90°. In the illustrated example, both the angle θ1 and the angle θ2 are more than 90°. The angles θ1 and θ2 are, for example, 90° or more and 135° or less. When at least one of the angle θ1 and the angle θ2 is 90° or more, the strength of the first portion 62 of the first bump 60a can be increased, and the space between the coupling terminal 13 of the case 10 and the first electrode layer 52 can be stably ensured.

The angles θ1 and θ2 can be controlled by the type of the third resist layer 84 and the exposure dose of the third resist layer 84.

Further, the width W2 of the second portion 64 of the first bump 60a is not particularly limited. For example, the width W2 of a first bump 60a illustrated in FIG. 20 is smaller than the width W2 of the first bump 60a illustrated in FIG. 18. The width W2 is controlled by, for example, the duration of the plating process when forming the first bump 60a.

The above-described embodiments and modifications are merely examples, and the present disclosure is not limited thereto. For example, each of the embodiments and each of the modifications may be combined as appropriate.

The present disclosure includes configurations substantially the same as the configurations described in the embodiments, for example, configurations having the same functions, methods, and results, or configurations having the same purposes and effects. Further, the present disclosure includes configurations in which non-essential portions of the configurations described in the embodiments are replaced. In addition, the present disclosure includes configurations that achieve the same effects as the configurations described in the embodiments or configurations capable of achieving the same object. Furthermore, the present disclosure includes configurations in which a known technique is added to the configurations described in the embodiments.

The following content is derived from the above-described embodiments and modifications.

An aspect of a vibrator element includes: a piezoelectric substrate; an electrode provided on the piezoelectric substrate; and a bump provided on a surface of the electrode, a cross-sectional shape of the bump taken along a thickness direction of the piezoelectric substrate includes a first portion and a second portion protruding from the first portion, the first portion has a first side and a second side extending from the surface of the electrode, the second portion has a third side intersecting the first side and a fourth side intersecting the second side, and a width of the second portion in a direction orthogonal to the thickness direction is larger than a width of the first portion in the direction orthogonal to the thickness direction.

According to this vibrator element, it is possible to improve the production efficiency.

In an aspect of the vibrator element, the third side and the fourth side may be parallel to the surface of the electrode.

According to this vibrator element, the bump can be formed to be thicker than the resist layer for forming the bump.

In an aspect of the vibrator element, at least one of an angle at which the first side and the third side intersect each other and an angle at which the second side and the fourth side intersect each other may be less than 90°.

According to this vibrator element, when the vibrator element is joined to the case, the joining strength between the vibrator element and the case can be improved.

In an aspect of the vibrator element, at least one of an angle at which the first side and the third side intersect each other and an angle at which the second side and the fourth side intersect each other may be 90° or more.

According to this vibrator element, the strength of the first portion can be increased.

In an aspect of the vibrator element, a length of the bump in the thickness direction may be 20 μm or more.

According to this vibrator element, when the vibrator element is joined to the case using a joining member, it is possible to reduce the possibility that the joining member is in contact with the electrode.

An aspect of the vibrator element may include a plurality of the bumps.

According to this vibrator element, when the vibrator element is joined to the case, the joining strength between the vibrator element and the case can be improved.

An aspect of a vibrator device includes: an aspect of the vibrator element; and a case including a coupling terminal and housing the vibrator element, and the second portion of the bump is coupled to the coupling terminal.

According to this vibrator device, it is possible to improve the production efficiency.

An aspect of a vibrator device includes: an aspect of the vibrator element; a case including a coupling terminal and housing the vibrator element; and a joining member fixing the bump to the coupling terminal, and the joining member reaches to an inner corner portion where the first side and the third side of the bump intersect each other and an inner corner portion where the second side and the fourth side of the bump intersect each other.

According to this vibrator device, it is possible to improve the production efficiency.

What is claimed is:

1. A vibrator element comprising:
a piezoelectric substrate;
an electrode provided on the piezoelectric substrate; and
a bump provided on a surface of the electrode, wherein
a cross-sectional shape of the bump taken along a thickness direction of the piezoelectric substrate includes
a first portion and a second portion protruding from the first portion,
the first portion has a first side and a second side extending from the surface of the electrode,
the second portion has a third side intersecting the first side and a fourth side intersecting the second side, and
a width of the second portion in a direction orthogonal to the thickness direction is larger than a width of the first portion in the direction orthogonal to the thickness direction.

2. The vibrator element according to claim 1, wherein
the third side and the fourth side are parallel to the surface of the electrode.

3. The vibrator element according to claim 1, wherein
at least one of an angle at which the first side and the third side intersect each other and an angle at which the second side and the fourth side intersect each other is less than 90°.

4. The vibrator element according to claim 1, wherein
at least one of an angle at which the first side and the third side intersect each other and an angle at which the second side and the fourth side intersect each other is 90° or more.

5. The vibrator element according to claim 1, wherein
a length of the bump in the thickness direction is 20 μm or more.

6. The vibrator element according to claim 1, comprising
a plurality of the bumps.

7. A vibrator device comprising:
the vibrator element according to claim 1; and
a case including a coupling terminal and housing the vibrator element, wherein
the second portion of the bump is coupled to the coupling terminal.

8. A vibrator device comprising:
the vibrator element according to claim 1;
a case including a coupling terminal and housing the vibrator element; and
a joining member fixing the bump to the coupling terminal, wherein
the joining member reaches to an inner corner portion where the first side and the third side of the bump intersect each other and an inner corner portion where the second side and the fourth side of the bump intersect each other.
